(19) United States
(12) Patent Application Publication
(10) Pub. No.: US 2005/0175080 A1
(43) Pub. Date: Aug. 11, 2005

(54) Equalizer status monitor

(76) Inventor: Aaron Reel Bouillett, Noblesville, IN (US)

Correspondence Address: THOMSON LICENSING INC., PATENT OPERATIONS, PO BOX 5312, PRINCETON, NJ, 08543-5312, US

(21) Appl. No.: 10/511,562

(22) PCT Filed: Apr. 11, 2003
(86) PCT No.: PCT/US03/11002

Related U.S. Application Data
(60) Provisional application No. 60/373,155, filed on Apr. 17, 2002.

(51) Int. Cl. H03K 5/159

(52) U.S. Cl. 375/229

(57) ABSTRACT

A system for monitoring the output of an adaptive channel equalizer in order to determine if convergence has been achieved. A slicer samples data from the equalizer during a predetermined period. The output data from the slicer is forwarded to a microprocessor in order to apply a test standard to the slicer data. For example, if one of every possible transmitted symbol is detected by the microprocessor, convergence is assumed to have occurred. If the test criterion is not met, a reset signal is sent to the equalizer.

The present patent application is based on and claims priority from Provisional U.S. Patent Application No. 60/373,155 of the same title filed on Apr. 17, 2002.

### BACKGROUND

1. Field of the Invention

This invention relates to generally to an equalizer for use in receiving digital communications signals, and more particularly to adaptive channel equalization of an image representative signal which may be processed by a High Definition Television (HDTV) receiver.

2. Background

An example of a portion of a prior art HDTV system 21 is depicted in FIG. 1. In such a system, a terrestrial broadcast signal 1 is forwarded to an input network that includes an RF tuning circuit 14 and an intermediate frequency processor 16 for producing an IF passband output signal 2. The broadcast signal 1 is a carrier suppressed eight bit vestigial sideband (VSB) modulated signal as specified by the Grand Alliance for HDTV standards. Such a VSB signal is represented by a one dimensional data symbol constellation where only one axis contains data to be recovered by the receiver 21. The passband IF output signal 2 is converted to an oversampled digital symbol datastream by an analog to digital converter (ADC) 19. The oversampled digital datastream 3 is demodulated to baseband by a digital demodulator and carrier recovery network 22.

The recovery of data from modulated signals conveying digital information in symbol form usually requires that three functions be performed by receiver 21. First is timing recovery for symbol synchronization, second is carrier recovery (frequency demodulation to baseband), and finally channel equalization. Timing recovery is a process by which a receiver clock (timebase) is synchronized to a transmitter clock. This permits a received signal to be sampled at optimum points in time to reduce slicing or truncation errors associated with decision directed processing of received symbol values. Adaptive channel equalization is a process of compensating for the effects of changing conditions and disturbances on the signal transmission channel. This process typically employs filters that remove amplitude and phase distortions resulting from frequency dependent, time variable characteristics of the transmission channel, thereby improving symbol decision capability.

Carrier recovery is a process by which a received RF signal, after being converted to a lower intermediate frequency passband (typically near baseband), is frequency shifted to baseband to permit recovery of the modulating baseband information. A small pilot signal at the suppressed carrier frequency is added to the transmitted signal 1 to assist in achieving carrier lock at the VSB receiver 21. The demodulation function performed by demodulator 22 is accomplished in response to the reference pilot carrier contained in signal 1. Unit 22 produces as an output a demodulated symbol datastream 4.

ADC 19 oversamples the input 10.76 Million Symbols per second VSB symbol datastream 2 with a 21.52 MHz sampling clock (twice the received symbol rate), thereby providing an oversampled 21.52 Msamples/sec datastream with two samples per symbol. An advantage of using a two sample per symbol scheme, as compared to one sample per symbol is for improved symbol timing acquisition and tracking, e.g. using a Gardner symbol timing recovery subsystem. Interconnected to ADC 19 and demodulator 22 is a segment sync and symbol clock recovery network 24. The network 24 detects and separates from random noise the repetitive data segment sync components of each data frame. The segment sync signals 6 are used to regenerate a properly phased 21.52 MHz clock which is used to control the datastream symbol sampling performed by ADC 19. A DC compensator 26 uses an adaptive tracking circuit to remove from the demodulated VSB signal 4 a DC offset component due to the presence of the pilot signal. Field sync detector 28 detects the field sync component by comparing every received data segment with an ideal field reference signal stored in the memory of the receiver 21. The field sync detector 28 also provides a training signal to channel equalizer 34, which will be discussed in more detail shortly. Examples of adaptive channel equalizers are disclosed in U.S. Pat. No. 6,490,007, entitled ADAPTIVE CHANNEL EQUALIZER, issued on Dec. 3, 2002 to Bouillet et al., and in U.S. Pat. No. 5,909,466, entitled ADAPTIVE EQUALIZER FOR DIGITAL COMMUNICATIONS SYSTEMS, issued on Jun. 1, 1999 to Labat et al. NTSC interference detection and filtering are performed by unit 5, an example of which is disclosed in U.S. Pat. No. 5,512,957, entitled METHOD AND APPARATUS FOR COMBATING CO-CHANNEL NTSC INTERFERENCE FOR DIGITAL TV TRANSMISSION, issued on Apr. 30, 1996, to Hulyalkar.

Equalizer 34 corrects channel distortions, but phase noise randomly rotates the symbol constellation. Phase tracking network 36 removes the residual phase and gain noise in the output signal received from equalizer 34, including phase noise which has not been removed by the preceding carrier recovery network 22 in response to the pilot signal. The phase corrected output signal 9 of tracking network 36 is then trellis decoded by unit 25, deinterleaved by unit 24, Reed-Solomon error corrected by unit 23 and descrambled by unit 27. The final step is to forward the decoded datastream 10 to audio, video and display processors 50.

The signal 7 is adaptively equalized by channel equalizer 34 which may operate in a combination of blind, training and decision directed modes. Equalizer 34 attempts to remove as much intersymbol interference as possible. The equalization process estimates the transfer function of the transmitted signal and applies the inverse of the transfer function to received signal 1 so as to reduce distortion effects caused by changing channel conditions and disturbances on the signal transmission channel. An adaptive equalizer is essentially a digital filter with an adaptive response to compensate for channel distortions. If the transmission characteristics of the communication channel are known or measured, then the equalization filter parameters can be set directly. After adjustment of the equalization filter parameters, the received signal is passed through the equalizer, which compensates for the non-ideal communication channel by introducing compensating “distortions” into the received signal which tend to cancel the distortions introduced by the communication channel.

Several well known algorithms are available for adapting the filter coefficients and thereby the filter response to converge the equalizer. However, in most situations such as in broadcasting, each receiver is in a unique location with respect to the transmitter. The characteristics of the communication channel are not known in advance. In those situations where the communication channel is not characterized in advance, or changes with time, an adaptive equalizer is used. An adaptive equalizer has variable parameters that are calculated at the receiver. The problem to be solved in an adaptive equalizer is how to adjust the equalizer filter parameters in order to restore signal quality to a performance level that is acceptable by subsequent error correction decoding. In some adaptive equalization systems, the parameters of the equalization filter are set using a predetermined reference signal (a training sequence), which is periodically sent from the transmitter to the receiver. The received training sequence is compared with the known training sequence to derive the parameters of the equalization filter. After several iterations of parameter settings derived from adaptation over successive training sequences, the equalization filter converges to a setting that tends to compensate for the distortion characteristics of the communications channel.

In blind equalization systems, the equalizer filter parameters are derived from the received signal itself without using a training sequence. In the prior art, it is known to adjust the equalizer parameters blindly using the Least Mean Squares (LMS) algorithm, in which the training symbols are replaced with hard decisions, or best estimates of the original input symbols. Blind equalization systems using LMS in this manner are referred to as decision directed (DD). The DD algorithm requires a good initial estimate of the input signal 1. For most realistic communication channel conditions, the lack of an initial signal estimate results in high decision error rates, which cause the successively calculated equalizer filter parameters to continue to fluctuate, rather than converge to a desired solution. The parameters are said to diverge in such a case.

Adaptive channel equalizers with infinite impulse response have the potential to diverge or adapt to an invalid state. When the equalizer is in such a divergent state, its output is both unusable and often undetectable by other monitoring schemes. Some mechanism is needed to monitor the output signal produced by an adaptive equalizer and detect when such a divergent or invalid condition exists.

Prior techniques for addressing this problem include monitoring the signal to noise ratio (SNR) at the equalizer output 8. For some of the divergent cases the SNR would be unreasonably high. A maximum SNR is assigned, and if the output signal exceeds the maximum SNR then the equalizer 34 is reset. Another technique is to monitor the forward error correction error counter 23 (the Reed-Solomon decoder). Under some circumstances the error counter increments rapidly when the equalizer output becomes unstable. In this case, the error counter is reset and then monitored after a prescribed interval. If the error rate exceeds a predetermined threshold during the interval, a divergent mode is deemed to exist and the equalizer 34 is reset. Either or both of these mechanisms may detect all divergent cases associated with the some equalizer architecture. However, the architecture of other equalization systems may operate in divergent modes that are not detected by either of the aforementioned techniques. Thus, another test is needed to fully verify the integrity of the equalizer output signal.

### SUMMARY OF THE INVENTION

The present invention addresses the problem of reliably detecting a divergent or unstable adaptive equalizer when used to recover data from modulated signals. The monitor of the present invention collects data samples from the output signal of the adaptive equalizer. The data is then sent to a slicer. A memory associated with the monitor contains a minimum threshold number of each output level expected to be present in the received signal. If the threshold number for each output level is not met, the adaptive equalizer is reset and the adaptive process begins anew. The benefit of slicing the data is a simplification of the test logic criteria thus a reduction in the complexity of the associated hardware.

### BRIEF DESCRIPTION OF THE DRAWING

FIG. 1 is a block diagram of a portion of a prior art high definition television receiver;

FIG. 2 is a block diagram of an HDTV receiver including an adaptive channel equalizer constructed according to the principles of the present invention; and

FIG. 3 is a flow chart depicting the implementation of the present invention.

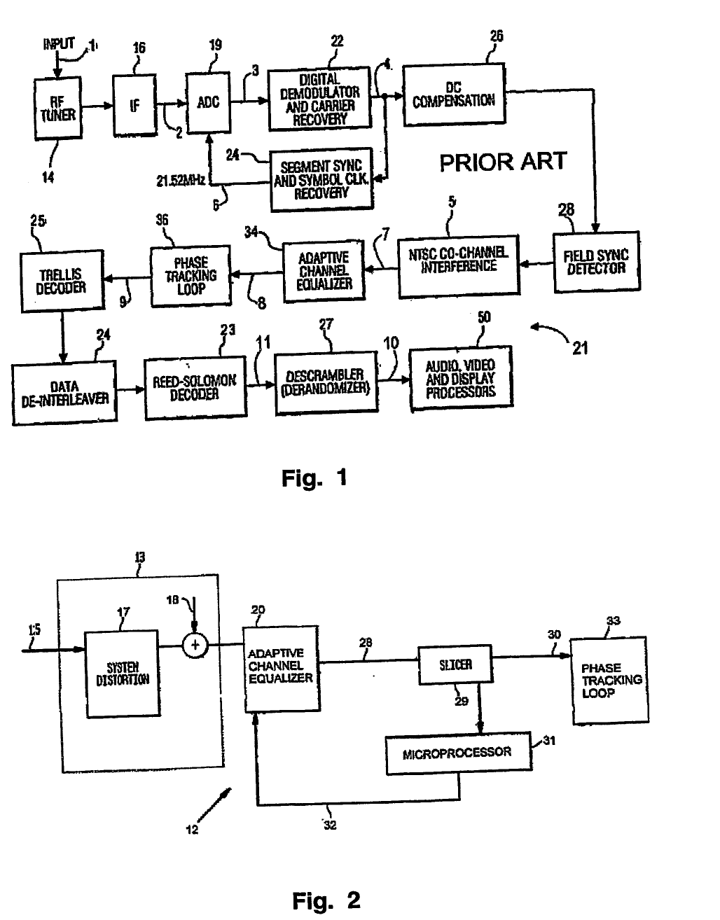

### DETAILED DESCRIPTION

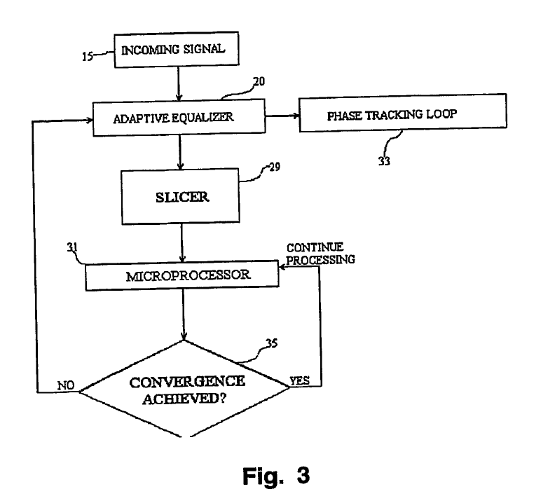

FIG. 2 depicts a portion of an HDTV receiver 12, and FIG. 3 illustrates a data flow chart, corresponding to FIG. 2, illustrating the flow of data through the system of FIG. 2. Corresponding elements in FIGS. 2 and 3 are designated by the same reference numbers, and will be discussed together below. The input signal 15 is received from a previous stage of the HDTV receiver such as an NTSC co-channel interference rejection network. The overall communication channel 13 introduces system distortion 17 and noise 18 into the signal 15. Referring to FIG. 3, the received signal 15 is the input to the adaptive channel equalizer 20, which is typically implemented as an infinite impulse response filter. The output 28 of the equalizer 20 is the input signal to the slicer 29, the slicer being a ‘nearest element’ decision device. The slicer 29 is responsive to the signal 28 at its input, and its output 30 is the projection of the nearest symbol value residing within the grid of constellation points. The output 30 of the slicer 29 therefore corresponds to the permissible discrete symbol values. For example, if the permissible transmitted symbol values are −1 and +1, the slicer will only output those values. An equalizer output of, for example, {0.9, −0.1, 0.5, −0.5} will therefore result in an output datastream 30 from slicer 29 of {1, −1, 1, −1}. Similarly, in the illustrated embodiment of an 8-VSB signal, the permissible symbol values are {7,5,3,1,−1,−3,−5,−7}. The slicer 29 may be a dedicated hardware circuit designed for its data gathering purpose, or it may be a microprocessor appropriately programmed to gather and examine relevant data. In any event, the slicer output datastream 30, in addition to being forwarded to a subsequent block of the receiver 12 such as phase tracking loop 33, is also coupled to a monitoring circuit 31, which in FIGS. 2 and 3 is a microprocessor 31, for further evaluation.

In order to determine whether convergence has been achieved, a data sample consisting of a plurality of sliced samples gathered during a predetermined time period must be examined by microprocessor 31. In a preferred embodiment, the time period must be sufficient to obtain approximately 400,000 symbols. For a 10 MHz clock rate, the symbol rate is 100 nanoseconds and so the time period required for gathering data is approximately 40 milliseconds. An additional time period is required in order for the microprocessor 31 to examine the collected slicer data. Although fewer symbols (e.g. 1000) may provide a statistically valid sample for determining convergence, confidence is increased as the number of symbols examined are increased. As a practical matter, the equalizer 20 has approximately 200 milliseconds to reach convergence. If after that time has elapsed convergence has not been reached, as indicated at step 35, the microprocessor 31 sends a reset signal 32 to equalizer 20, which begins acquisition again in response.

The microprocessor 31 contains or has access to storage memory in which the gathered slicer data 29 and suitable test protocols or criteria are stored. The criteria applied by the microprocessor 31 in determining convergence can be variable and in some cases user programmable. Due to the large number of symbols gathered during the test period, one suitable test criterion is the occurrence at least once of each of the possible transmitted symbol values in the sample of symbols. That is, every one of the permissible symbol values ({7,5,3,1,−1,−3,−5,−7}) must occur at least once in the sample of 400,000 symbols gathered. If so, the equalizer is deemed to have converged. If not, then a reset signal is sent to the equalizer, as described above. Depending on the characteristics of the transmitted signal, the criterion can be modified to require a larger number of each possible symbol, or only some fraction of all possible symbol values. One skilled in the art will understand how to evaluate these characteristics and derive appropriate criteria for them.

Although in the illustrated embodiment, the monitoring circuit is formed by a microprocessor 31 programmed in a known manner to perform the processing described above and illustrated in FIG. 3, one skilled in the art will understand that the monitoring circuit may also be fabricated as dedicated hardware for performing this processing, including separate memory for storing the sampled symbols and the testing criteria, or as a combination of separate hardware and a microprocessor.

1. An apparatus for determining convergence of an equalizer, comprising:
an equalizer output signal;
a nearest element decision device, the nearest element decision device receiving the equalizer output signal and creating a decision device output signal containing permissible symbol values; and
a monitoring circuit, the monitoring circuit receiving the decision device output signal and applying a test criterion to data contained in the decision device output signal so as to determine equalizer convergence.

2. The apparatus of claim 1, wherein the equalizer is formed to include an infinite impulse response filter.

3. The apparatus of claim 1, wherein the nearest element decision device is a slicer.

4. The apparatus of claim 1, wherein the monitoring circuit receives the decision device output signal for a predetermined period of time representing an acquisition of a desired number of transmitted symbol values.

5. The apparatus of claim 4, further comprising a memory, the memory being coupled to the monitoring circuit and being adapted to store decision device output data and test criteria.

6. The apparatus of claim 5, wherein the test criteria for determining equalizer convergence includes identifying a desired sample of transmitted symbol values.

7. The apparatus of claim 6, wherein the desired sample of transmitted symbol values includes at least one of every possible symbol value.

8. The apparatus of claim 1, wherein the monitoring circuit is coupled to the equalizer, the monitoring circuit resetting the equalizer when the equalizer diverges.

9. The apparatus of claim 1, wherein the monitoring circuit is coupled to the equalizer, the monitoring circuit resetting the equalizer when the equalizer achieves an invalid state.

10. The apparatus of claim 1, wherein the equalizer output signal includes an image representative datastream containing data packets.

11. The apparatus of claim 1, wherein the monitoring circuit is a microprocessor.

12. An equalizer status monitoring device for use in a digital communication system, the device including an adaptive channel equalizer, a slicer and a monitoring circuit, wherein the digital communications system receives a vestigial sideband modulated signal containing high definition video information represented by a multiple level symbol constellation, the data having a data frame format constituted by a succession of data frames, the adaptive channel equalizer generating a first output signal which is input to the slicer, the slicer generating a second output signal which is input to the monitoring circuit, the monitoring circuit applying a test criteria to the second output signal to determine convergence of the adaptive channel equalizer.

13. The system of claim 12, wherein the monitoring circuit is coupled to the adaptive channel equalizer and resets the adaptive channel equalizer when the adaptive channel equalizer diverges.

14. The system of claim 12, wherein the monitoring circuit is coupled to the adaptive channel equalizer and resets the adaptive channel equalizer when the adaptive channel equalizer assumes an invalid state.

15. The system of claim 12, wherein the test criteria for determining convergence requires identifying at least some transmitted symbol values.

16. The system of claim 12, wherein the adaptive channel equalizer further comprises an infinite impulse response filter.

17. The system of claim 12, wherein the test criteria for determining convergence requires identifying at least one of each possible transmitted symbol value.

18. The system of claim 12 wherein the monitoring circuit is a microprocessor.

19. In a digital communications receiver including an adaptive equalization filter that desirably achieves a state of convergence and which undesirably achieves a state of divergence or an invalid state, a method of monitoring the state of the equalization filter comprising the steps of:
coupling an output signal from the equalization filter to a monitoring circuit;
causing the monitoring circuit to examine data contained within the output signal for a finite time period;
causing the monitoring circuit to apply a test protocol to the examined data; and
causing the monitoring circuit to reset the equalization filter when the test protocol detects a state of divergence.

20. A method according to claim 19, further comprising the step of causing the monitoring circuit to reset the equalization filter when the test protocol detects that the equalization filter has achieved an invalid state.

21. A method according to claim 19, further comprising the steps of:
coupling the equalization filter output signal to a slicer; and
coupling the slicer to the monitoring circuit such that the monitoring circuit examines data generated by the slicer.

22. A method according to claim 21, wherein the test protocol requires detection of each possible transmitted symbol value within the data generated by the slicer in order to find that the equalization filter has achieved a state of convergence.

23. The method of claim 19 wherein the monitoring circuit is a microprocessor.
